(19) United States
(12) Patent Application Publication
(10) Pub. No.: US 2026/0205153 A1
(43) Pub. Date: Jul. 16, 2026

(54) RADIO SYSTEM INCLUDING ONE OR MORE TUNABLE LOW PASS FILTERS FOR SUPPRESSING HARMONICS AND AN ASSOCIATED METHOD

(71) Applicant: ELBIT SYSTEMS C4I AND CYBER LTD., Netanya (IL)

(72) Inventors: Avraham HAGAY, Netanya (IL); Mark WAISBLAY, Netanya (IL)

(21) Appl. No.: 19/437,396

(22) Filed: Dec. 31, 2025

Related U.S. Application Data
(63) Continuation of application No. PCT/IL2024/050618, filed on Jun. 24, 2024.

(30) Foreign Application Priority Data
Jul. 2, 2023 (IL) 304184

(51) Int. Cl. H04B 1/40; H04B 1/04

(52) U.S. Cl. CPC H04B 1/40; H04B 1/0475

(57) ABSTRACT

A radio system comprises: a wide-band transmitter configured to generate one or more radio transmission signals; and one or more tunable low pass filters (LPFs), coupled between the wide-band transmitter and a transmission antenna, each of the tunable LPFs being configured to filter one or more given transmission signals of the radio transmission signals. Each of the tunable LPFs includes a printed part consisting of printed components, and a discrete part consisting of discrete components. The radio system further comprises a controller configured to tune a given tunable LPF of the tunable LPFs for filtering a given transmission signal of the given transmission signals that are filtered by the given tunable LPF, by manipulating the printed part and the discrete part of the given tunable LPF.

### TECHNICAL FIELD

The invention relates to a radio system including one or more tunable low pass filters for suppressing harmonics and an associated method.

### BACKGROUND

Conventionally, a radio system having a high-power wide-band transmitter includes a large number of low pass filters (LPFs) for filtering out harmonics that are generated by the transmitter. The use of a large number of LPFs in a radio system has deficiencies. For each additional LPF that is included in the radio system, a transmission power of transmission signals at the transmission antenna is reduced. Specifically, for each additional LPF, there is a greater attenuation of transmission signals by the Radio Frequency (RF) switch that routes the transmission signals to the LPFs and by the RF switch that routes the transmission signals from the LPFs to the transmission antenna. Moreover, each additional LPF includes energy consuming components, such as capacitors and induction coils, thereby further attenuating transmission signals. The attenuation of the transmission signals results in the reduced transmission power of the transmission signals at the transmission antenna. Another deficiency resulting from each additional LPF that is included in the radio system is that the size of the radio system increases with each LPF that is included in the radio system.

The present disclosure addresses the aforementioned deficiencies by including one or more tunable LPFs in the radio system.

References considered to be relevant as background to the presently disclosed subject matter are listed below. Acknowledgement of the references herein is not to be inferred as meaning that these are in any way relevant to the patentability of the presently disclosed subject matter.

U.S. Patent Application Publication No. 2015/0235971, published on Aug. 20, 2015, discloses an apparatus and method for a frequency based integrated circuit that selectively filters out unwanted bands or regions of interfering frequencies utilizing one or more tunable notch or bandpass filters or tunable low or high pass filters capable of operating across multiple frequencies and multiple bands in noisy RF environments. The tunable filters are fabricated within the same integrated circuit package as the associated frequency-based circuitry, thus minimizing R, L, and C parasitic values, and also allowing residual and other parasitic impedance in the associated circuitry and IC package to be absorbed and compensated.

U.S. Pat. No. 7,567,782, published on Jul. 28, 2009, provides methods and apparatus to enable a transceiver or transmitter including a single PA line-up to transmit signals having frequencies in two or more different frequency bands, and/or having two or more different modulation types, and/or having two or more different RF power levels. The single PA line-up includes at least one variable matching circuit and a variable harmonic filter to tune match and tune filter communication signals prior to transmission. The variable matching circuit and the variable harmonic filter each include at least one variable capacitive element that switches ON/OFF depending on whether a low frequency signal or a high frequency signal is being transmitted. Each variable capacitive element includes separate direct current and radio frequency terminals to enable the single PA line-up to change signal modulation and/or RF power levels in addition to frequencies.

Singhal, H. K. and Rawat, K., “Digitally Assisted Harmonic Cancellation for Multi-Octave Filter-Less Transmitter,” IEEE Access, Volume 8, 7 Apr. 2020, DOI: 10.1109/ACCESS.2020.2986264, presents and demonstrates the design of a filter-less transmitter architecture with digitally assisted harmonic cancellation. A neural network is used to model the harmonics as well as intermodulation distortion (IMD) for digital predistortion applications. This neural network-based harmonic modeling does not require any reference signal to be injected at the input of Power Amplifier (PA), which is an in-house 10 Watts PA operating from Very High Frequency (VHF) to L-band. This PA is used along with an agile Radio Frequency (RF) transceiver. The receiver of the transceiver captures the nonlinearity of the PA in terms of harmonics as well as IMD components for modeling and predistortion. The architecture can handle all types of distortions due to hardware as well as PA nonlinearity. Besides, it is also able to cancel the harmonics using a harmonic injection in the feed-forward configuration. The scheme is demonstrated to transmit 5 MHz LTE signal at different frequencies over the range of 100 MHz to 400 MHz. In such a case, the second and third harmonics appear over the frequency range from 200 MHz to 1.2 GHz, which are within the amplification range of PA, yet they are suppressed without using any filter at the output. More than −40 dBc harmonic rejection is achieved over the entire operating range of this filter-less transmitter. The adjacent channel leakage ratio (ACLR) is always better than −45 dBc after applying digital predistortion.

U.S. Patent Application Publication No. 2010/0157858, published Jun. 24, 2010, presents architectures and implementations of a transceiver system for wireless communications, the system including one or more antennas supporting a single frequency band or multiple frequency bands, a transmit circuit, a receive circuit, and an isolation circuit that is coupled to the one or more antennas and the transmit and receive circuits and provides adequate isolation between the transmit circuit and the receive circuit.

U.S. Patent Application Publication No. 2010/0309901, published Dec. 9, 2010, discloses a multiband transceiver including transmit sub-circuits (TSCs) arranged in parallel, a multiplexer receiving RF signals from the TSCs at input ports, and a directional coupler (DC). Each TSC is configured to support communications in a respective frequency band. The multiplexer is configured to route signals from the input ports to a common output port and to reduce harmonic distortion induced by the TSCs. DC has an input port connected to the common output port, a transmitted port connected to an antenna port, and a coupled port coupling a portion of the RF signal to a common feedback loop (CFL). The CFL provides a feedback signal coupled to each TSC. Each TSC is responsive to the feedback signal for maintaining a controlled power output at the antenna port over a range of frequencies.

U.S. Pat. No. 5,893,026, published Apr. 6, 1999, discloses a low pass filter capable of passing a radio paging signal of good quality through suppressing harmonics in a radio paging transmitter. The low pass filter of the radio paging transmitter comprises: a first filter of a π type for suppressing harmonic of a radio paging signal outputted, which is connected to an output terminal of the radio paging transmitter; and, a second filter for suppressing second and third harmonic or more of the radio paging signal, which is connected between the first filter and an antenna and comprised with multistage plane panel capacitors and parallel inductance and capacitors connected between the plane panel capacitors.

### GENERAL DESCRIPTION

In accordance with a first aspect of the presently disclosed subject matter, there is provided a radio system, comprising: a wide-band transmitter configured to generate one or more radio transmission signals; one or more tunable low pass filters (LPFs), coupled between the wide-band transmitter and a transmission antenna, each tunable LPF of the tunable LPFs being configured to filter one or more given transmission signals of the radio transmission signals, and including: a printed part consisting of printed components; and a discrete part consisting of discrete components; and a controller configured to tune a given tunable LPF of the tunable LPFs for filtering a given transmission signal of the given transmission signals that are filtered by the given tunable LPF, by manipulating the printed part and the discrete part of the given tunable LPF.

In some cases, a lowest cutoff frequency at which the given tunable LPF is capable of operating is less than 65% of a highest cutoff frequency at which the given tunable LPF is capable of operating.

In some cases, a lowest cutoff frequency at which each tunable LPF of the tunable LPFs is capable of operating is less than 65% of a highest cutoff frequency at which the respective tunable LPF is capable of operating.

In some cases, the printed components in the given tunable LPF include physical attributes that enable the given tunable LPF to operate at a highest cutoff frequency at which the given tunable LPF is capable of operating.

In some cases, the discrete components in the given tunable LPF include PIN diodes that are connected to the printed part of the given tunable LPF.

In some cases, the manipulating of the discrete part of the given tunable LPF includes controlling a state of the PIN diodes.

In some cases, the manipulating of both the discrete part and the printed part of the given tunable LPF is achieved by changing a state of one or more of the PIN diodes in the given tunable LPF.

In some cases, the printed components in the printed part of the given tunable LPF include filtering printed components.

In some cases, the manipulating of the printed part of the given tunable LPF includes manipulating electrical values of the filtering printed components.

In some cases, the manipulating of the printed part of the given tunable LPF includes manipulating an electrical length of one or more physical lines in the printed part.

In some cases, the given tunable LPF is capable of operating at three or more cutoff frequencies.

In some cases, a lowest cutoff frequency at which the given tunable LPF is capable of operating is less than 65% of a highest cutoff frequency at which the given tunable LPF is capable of operating; and parasitic characteristics of the PIN diodes enable the given tunable LPF to operate at the lowest cutoff frequency.

In some cases, the parasitic characteristics include: (a) a series resistance at 10 milliamperes (mA) that is less than one Ohm (Ω) to form a short circuit, and (b) a capacitance at 50-400 Volts (V) that is between 0.33 and 0.37 picofarads (pF) to form an open circuit.

In accordance with a second aspect of the presently disclosed subject matter, there is provided a tunable low-pass filter (LPF), comprising: a printed part consisting of printed components; and a discrete part consisting of discrete components; wherein the tunable LPF is tunable by manipulating the printed part and the discrete part; and wherein a lowest cutoff frequency at which the tunable LPF is capable of operating is less than 65% of a highest cutoff frequency at which the tunable LPF is capable of operating.

In some cases, the printed components include physical attributes that enable the tunable LPF to operate at a highest cutoff frequency at which the tunable LPF is capable of operating.

In some cases, the discrete components include PIN diodes that are connected to the printed part of the tunable LPF.

In some cases, the manipulating of the discrete part includes controlling a state of the PIN diodes.

In some cases, the manipulating of both the discrete part and the printed part of the tunable LPF is achieved by changing a state of one or more of the PIN diodes in the tunable LPF.

In some cases, the printed components in the printed part of the given tunable LPF include filtering printed components.

In some cases, the manipulating of the printed part includes manipulating electrical values of the filtering printed components.

In some cases, the manipulating of the printed part includes manipulating an electrical length of one or more physical lines in the printed part.

In some cases, the tunable LPF is capable of operating at three or more cutoff frequencies.

In some cases, parasitic characteristics of the PIN diodes enable the tunable LPF to operate at the lowest cutoff frequency.

In some cases, the parasitic characteristics include: (a) a series resistance at 10 milliamperes (mA) that is less than one Ohm (Ω) to form a short circuit, and (b) a capacitance at 50-400 Volts (V) that is between 0.33 and 0.37 picofarads (pF) to form an open circuit.

In accordance with a third aspect of the presently disclosed subject matter, there is provided a method for processing a radio transmission signal, the method comprising: tuning a tunable low pass filter (LPF), by a controller, for filtering the radio transmission signal; generating, by a wide-band transmitter, the radio transmission signal; and filtering, by the tunable LPF, the radio transmission signal; wherein the tunable LPF includes: a printed part consisting of printed components, and a discrete part consisting of discrete components; and wherein the tunable LPF is tuned by manipulating the printed part and the discrete part.

In some cases, a lowest cutoff frequency at which the tunable LPF is capable of operating is less than 65% of a highest cutoff frequency at which the tunable LPF is capable of operating.

In some cases, the printed components include physical attributes that enable the tunable LPF to operate at a highest cutoff frequency at which the tunable LPF is capable of operating.

In some cases, the discrete components include PIN diodes that are connected to the printed part.

In some cases, the manipulating of the discrete part includes controlling a state of the PIN diodes.

In some cases, the manipulating of both the discrete part and the printed part is achieved by changing a state of one or more of the PIN diodes.

In some cases, the printed components in the printed part include filtering printed components.

In some cases, the manipulating of the printed part includes manipulating electrical values of the filtering printed components.

In some cases, the manipulating of the printed part includes manipulating an electrical length of one or more physical lines in the printed part.

In some cases, the tunable LPF is capable of operating at three or more cutoff frequencies.

In some cases, a lowest cutoff frequency at which the tunable LPF is capable of operating is less than 65% of a highest cutoff frequency at which the tunable LPF is capable of operating; and parasitic characteristics of the PIN diodes enable the tunable LPF to operate at the lowest cutoff frequency.

In some cases, the parasitic characteristics include: (a) a series resistance at 10 milliamperes (mA) that is less than one Ohm (Ω) to form a short circuit, and (b) a capacitance at 50-400 Volts (V) that is between 0.33 and 0.37 picofarads (pF) to form an open circuit.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings. The dimensions of components and features shown in the drawings are chosen for convenience and clarity of presentation and are not necessarily to scale. In the drawings:

FIG. 1 is a block diagram schematically illustrating one example of a radio system, in accordance with the presently disclosed subject matter;

FIG. 2 is a graph that schematically illustrates one example of frequency response functions for an ideal tunable LPF, in accordance with the presently disclosed subject matter;

FIG. 3 is one example of a Printed Circuit Board (PCB) design including two tunable LPFs, in accordance with the presently disclosed subject matter; and

FIG. 4 is a flowchart illustrating one example of a sequence of operations for processing a given radio transmission signal, in accordance with the presently disclosed subject matter.

### DETAILED DESCRIPTION

In the following detailed description, numerous specific details are set forth in order to provide a thorough understanding of the presently disclosed subject matter. However, it will be understood by those skilled in the art that the presently disclosed subject matter may be practiced without these specific details. In other instances, well-known methods, procedures, and components have not been described in detail so as not to obscure the presently disclosed subject matter.

In the drawings and descriptions set forth, identical reference numerals indicate those components that are common to different embodiments or configurations.

Unless specifically stated otherwise, as apparent from the following discussions, it is appreciated that throughout the specification discussions utilizing terms such as “generating”, “transmitting”, “filtering”, “obtaining”, “tuning”, “detecting” or the like, include actions and/or processes, including, inter alia, actions and/or processes of a computer, that manipulate and/or transform data into other data, said data represented as physical quantities, e.g. such as electronic quantities, and/or said data representing the physical objects. The terms “computer”, “processor”, “processing circuitry” and “controller” should be expansively construed to cover any kind of electronic device with data processing capabilities, including, by way of non-limiting example, a personal desktop/laptop computer, a server, a computing system, a communication device, a smartphone, a tablet computer, a smart television, a processor (e.g. digital signal processor (DSP), a microcontroller, a field-programmable gate array (FPGA), an application specific integrated circuit (ASIC), etc.), a group of multiple physical machines sharing performance of various tasks, virtual servers co-residing on a single physical machine, any other electronic computing device, and/or any combination thereof.

As used herein, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure or characteristic described in connection with the embodiment(s) is included in at least one embodiment of the presently disclosed subject matter. Thus the appearance of the phrase “one case”, “some cases”, “other cases” or variants thereof does not necessarily refer to the same embodiment(s).

It is appreciated that, unless specifically stated otherwise, certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination.

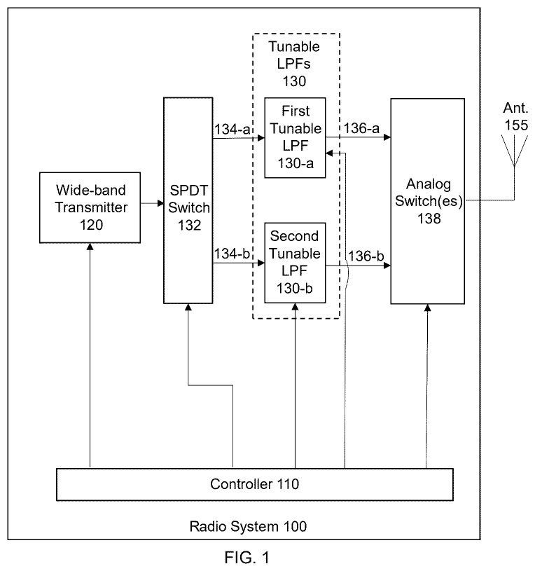

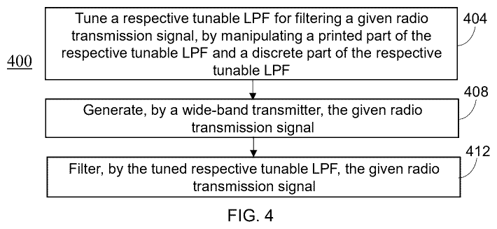

In embodiments of the presently disclosed subject matter, fewer, more and/or different stages than those shown in FIG. 4 may be executed. FIG. 1 illustrates a general schematic of the architecture of a radio system, in accordance with embodiments of the presently disclosed subject matter. Each module in FIG. 1 can be made up of any combination of software, hardware and/or firmware that performs the functions as defined and explained herein. The modules in FIG. 1 may be centralized in one location or dispersed over more than one location. In other embodiments of the presently disclosed subject matter, the system may comprise fewer, more, and/or different modules than those shown in FIG. 1.

Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that may be executed by the system and should be applied mutatis mutandis to a non-transitory computer readable medium that stores instructions that may be executed by the system.

Any reference in the specification to a non-transitory computer readable medium should be applied mutatis mutandis to a system capable of executing the instructions stored in the non-transitory computer readable medium and should be applied mutatis mutandis to method that may be executed by a computer that reads the instructions stored in the non-transitory computer readable medium.

Attention is now drawn to FIG. 1, a block diagram schematically illustrating one example of a radio system 100, in accordance with the presently disclosed subject matter.

In accordance with the presently disclosed subject matter, radio system 100 includes a controller 110, a wide-band transmitter 120 and one or more tunable low pass filters (LPFs) 130 that are coupled between wide-band transmitter 120 and a transmission antenna 155.

Controller 110 can include one or more processing units (e.g. central processing units), microprocessors, microcontrollers (e.g. microcontroller units (MCUs)) or any other computing devices or modules, including multiple and/or parallel and/or distributed processing units, which are adapted to independently or cooperatively process data for controlling relevant resources of the radio system 100 and for enabling operations related to the resources of the radio system 100.

Controller 110 is configured to provide the transmitter 120 with transmission data. Transmitter 120 is configured to generate one or more radio transmission signals that include the transmission data, for transmission by a transmission antenna 155. In some cases, the wide-band transmitter 120 can be powered at 10 Watts or more. In some cases, the transmitter 120 is configured to generate radio transmission signals in the Ultrahigh Frequency (UHF) band. Additionally, or alternatively, in some cases, the transmitter 120 is configured to generate radio transmission signals in the Super-high Frequency (SHF) band.

The one or more tunable LPFs 130 are configured to filter the radio transmission signals in order to suppress undesired frequency components in the radio transmission signals, including, inter alia, harmonics (second harmonics, third harmonics, etc.) of the transmission carrier frequencies of the radio transmission signals.

If two or more tunable LPFs 130 (i.e., a tunable LPF filter bank) are coupled between the transmitter 120 and the transmission antenna 155, an input routing Radio Frequency (RF) switch (e.g., Single Pole Double Throw (SPDT) switch 132) is provided to route each of the radio transmission signals to one of the tunable LPFs 130, and an output routing RF switch(es) (e.g., an analog switch(es) 138) is provided to route (e.g., to the transmission antenna 155) the radio transmission signals that are output from the tunable LPFs 130. In the non-limiting example of a radio system 100 that is shown in FIG. 1, two tunable LPFs 130 (first tunable LPF 130-a, second tunable LPF 130-b) are provided, and accordingly, the input routing RF switch (e.g., SPDT switch 132) includes two output ports (134-a and 134-b) and the output routing RF switch(es) (e.g., analog switch(es) 138) includes two input ports (136-a and 136-b).

Controller 110 can be configured to tune each of the tunable LPFs 130, and control the input routing RF switch (e.g., SPDT switch 132) and the output routing RF switch(es) (e.g., analog switch(es) 138) for routing the radio transmission signals to and from the tunable LPFs 130.

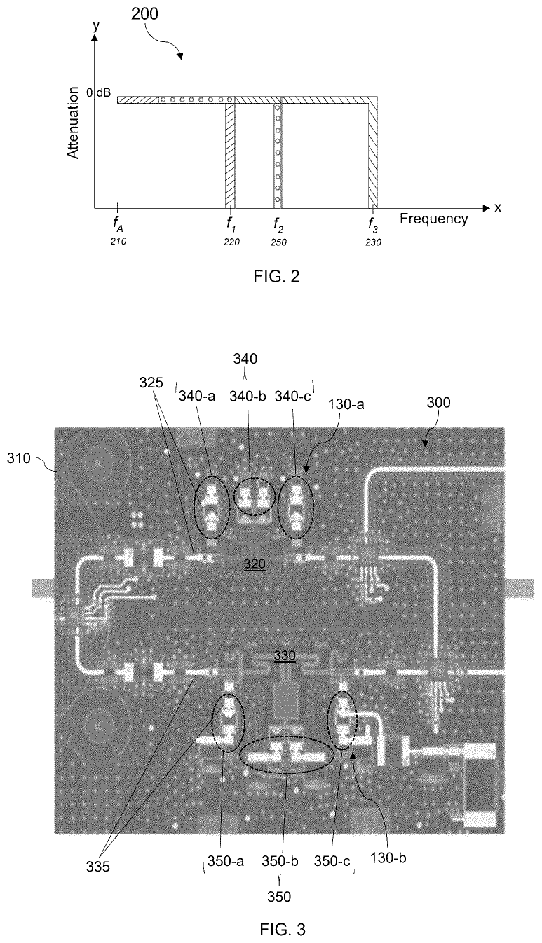

Each of the tunable LPFs 130 is tunable to two or more cut-off frequencies, as detailed further herein, inter alia with reference to FIGS. 2 and 3. In accordance therewith, a number of LPFs 130 in the radio system 100 can be reduced relative to a radio system that includes non-tunable LPFs, while maintaining or increasing the number of cutoff frequencies provided by the LPFs 130.

For example, if, for a radio system that includes non-tunable LPFs, four non-tunable LPFs must be provided to effectively filter out undesired frequency components (including, inter alia, harmonics) in the radio transmission signals, in the radio system 100 of the present disclosure, two tunable LPFs (130-a, 130-b) that are each tunable to two cut-off frequencies can achieve this functionality, as detailed further herein, inter alia with reference to FIG. 2. In some cases, at least one of the tunable LPFs 130 can be manufactured to be tunable to three or more cut-off frequencies, as detailed further herein, inter alia with reference to FIG. 2, resulting in two tunable LPFs 130 in the radio system 100 that are capable of providing a larger number of cutoff frequencies than four non-tunable LPFs in a conventional radio system. In some cases, at least one of the cut-off frequencies provided by at least one of the tunable LPFs 130 is within the UHF band. Additionally, or alternatively, in some cases, at least one of the cut-off frequencies provided by at least one of the tunable LPFs 130 is within the SHF band.

The reduction in the number of LPFs 130 in the radio system 100 relative to a radio system that includes non-tunable LPFs results in an increased transmission power of the radio transmission signals at the transmission antenna 155 for at least the following reasons: (a) the use of fewer LPFs 130 in the radio system 100 enables the use of routing RF switches (e.g., 132, 138) having fewer ports, resulting in less attenuation of the radio transmission signals, and (b) each of the LPFs 130 includes energy consuming components, e.g., capacitors and induction coils, that attenuate the radio transmission signals. Moreover, the reduced number of LPFs 130 in the radio system 100 reduces the real estate (i.e., circuit board) space in the radio system 100 that is occupied by the LPFs 130 relative to a radio system that includes non-tunable LPFs.

In some cases, at least one of the tunable LPFs 130 is capable of operating at a lowest cutoff frequency that is less than 65% (e.g., less than 62%, less than 60%, less than 57%, less than 55%, less than 53%, etc.) of a highest cutoff frequency at which the respective tunable LPF (e.g., 130-a, 130-b) is capable of operating. In some cases, each of the tunable LPFs 130 is capable of operating at a lowest cutoff frequency that is less than 65% (e.g., less than 62%, less than 60%, less than 57%, less than 55%, less than 53%, etc.) of a highest cutoff frequency at which the respective tunable LPF (e.g., 130-a, 130-b) is capable of operating.

Attention is now drawn to FIG. 2, a graph 200 that schematically illustrates one example of frequency response functions for an ideal tunable LPF (e.g., 130-a, 130-b), in accordance with the presently disclosed subject matter. The y-axis represents the attenuation of signals (e.g., radio transmission signals) that pass through the tunable LPF (e.g., 130-a, 130-b). The x-axis represents frequency. In some cases, the tunable LPF (e.g., 130-a, 130-b) can have two potential frequency response functions (i.e., can operate in two frequency bands). That is, the tunable LPF (e.g., 130-a, 130-b) can be tuned, at any given time, to: (a) pass signal components within a frequency range between frequency f_{A} 210 and a cutoff frequency f₁ 220, resulting in a frequency response function that is partially shaded by backslashes in FIG. 2, or (b) pass signal components within a frequency range between frequency f_{A} 210 and a cutoff frequency f₃ 230, resulting in a frequency response function that is partially shaded by forward slashes in FIG. 2. The need for a LPF that can pass signal components of radio transmission signals within a frequency range between frequency f_{A} 210 and a frequency f₁ 220 is to effectively filter out harmonics (particularly, second harmonics) of radio transmission signals having transmission carrier frequencies within the frequency range between frequency f_{A} 210 and frequency f₁ 220. That is, if a non-tunable LPF was to be provided that passes signal components of radio transmission signals within a frequency range between f_{A} 210 and f₃ 230, then the second harmonics of at least some of the radio transmission signals having a fundamental transmission frequency between f_{A} 210 and f₁ 220 would also be passed by the non-tunable LPF. To account for this, conventionally, a non-tunable LPF configured to pass signal components within a frequency range between frequency f_{A} 210 and cutoff frequency f₁ 220 is dedicated to pass radio transmission signals having transmission carrier frequencies within the frequency range between frequency f_{A} 210 and frequency f₁ 220 while filtering out the harmonics of such radio transmission signals, and another non-tunable LPF configured to pass signal components within a frequency range between frequency f_{A} 210 and cutoff frequency f₃ 230 is dedicated to pass radio transmission signals having transmission carrier frequencies within the frequency range between frequency f₁ 220 and frequency f₃ 230 while filtering out the harmonics of such radio transmission signals. In contrast, in the present disclosure, a single tunable LPF (e.g., 130-a, 130-b) is provided instead of two non-tunable LPFs, wherein the tunable LPF can be tuned, for example, to: (a) pass signal components within a first frequency range between frequency f_{A} 210 and cutoff frequency f₃ 230 in order to pass radio transmission signals having transmission carrier frequencies within the frequency range between frequency f₁ 220 and frequency f₃ 230 while effectively filtering out the harmonics of such radio transmission signals, or (b) pass signal components within a second frequency range between frequency f_{A} 210 and a cutoff frequency f₁ 220 (being a lower part of the first frequency range) in order to pass radio transmission signals having transmission carrier frequencies within the frequency range between frequency f_{A} 210 and frequency f₁ 220 while effectively filtering out the harmonics of such radio transmission signals. In some cases, the cutoff frequency f₁ 220 can be less than 65% (e.g., less than 62%, less than 60%, less than 57%, less than 55%, less than 53%, etc.) of the cutoff frequency f₃ 230, as detailed earlier herein, inter alia with reference to FIG. 1.

In some cases, the tunable LPF (e.g., 130-a, 130-b) can have three or more potential frequency response functions (i.e., can operate in three or more frequency bands). For example, the tunable LPF (e.g., 130-a, 130-b) can be tuned, at any given time, to pass signal components within one of three frequency ranges, namely: (1) a frequency range between frequency f_{A} 210 and a cutoff frequency f₁ 220; (2) a frequency range between frequency f_{A} 210 and a cutoff frequency f₂ 250, resulting in a frequency response function that is partly occupied by circles in FIG. 2; or (3) a frequency range between frequency f_{A} 210 and a cutoff frequency f₃ 230. By tuning the tunable LPF (e.g., 130-a, 130-b) to pass signal components within a frequency range between frequency f_{A} 210 and a cutoff frequency f₁ 220, radio transmission signals having transmission carrier frequencies within the frequency range between frequency f_{A} 210 and frequency f₁ 220 can be passed while effectively filtering out the harmonics of such radio transmission signals. By tuning the tunable LPF (e.g., 130-a, 130-b) to pass signal components within a frequency range between frequency f_{A} 210 and a cutoff frequency f₂ 250, radio transmission signals having transmission carrier frequencies within the frequency range between frequency f₁ 220 and frequency f₂ 250 can be passed while effectively filtering out the harmonics of such radio transmission signals (i.e., while (potentially) more effectively filtering out the harmonics of such radio transmission signals than if the tunable LPF (e.g., 130-a, 130-b) was only tunable to two cutoff frequencies f₁ 220 and f₃ 230). To explain this, it is assumed that the cutoff frequency f₁ 220 is 550 MHz and the cutoff frequency f₃ 230 is 1 GHz. If the tunable LPF (e.g., 130-a, 130-b) is configured to include only cutoff frequencies f₁ 220 and f₃ 230, the second harmonic of a radio transmission signal having a fundamental transmission frequency of 570 MHz will be effectively filtered out by tuning the tunable LPF to pass signal components within the frequency range between f_{A} 210 and f₃ 230. However, since, in this case, the second harmonic of the radio transmission signal (1.14 GHz) is not well above the upper cutoff frequency f₃ 230 (1 GHz), it would be beneficial to tune the tunable LPF (e.g., 130-a, 130-b) to pass signal components within the frequency range between f_{A} 210 and f₂ 250 (e.g., 650 MHz), thereby potentially better filtering out the second harmonic (1.14 GHz) of the radio transmission signal (the second harmonic is well above f₂ 250). Further to the above, by tuning the tunable LPF (e.g., 130-a, 130-b) to pass signal components within a frequency range between frequency f_{A} 210 and a cutoff frequency f₃ 230, radio transmission signals having transmission carrier frequencies within the frequency range between frequency f₂ 250 and frequency f₃ 230 can be passed while effectively filtering out the harmonics of such radio transmission signals. In some cases, the cutoff frequency f₁ 220 can be less than 65% (e.g., less than 62%, less than 60%, less than 57%, less than 55%, less than 53%, etc.) of the cutoff frequency f₃ 230, as detailed earlier herein, inter alia with reference to FIG. 1.

It is to be noted that each of the frequency bands to which a tunable LPF (e.g., 130-a, 130-b) is tunable, in addition to a first frequency band f_{A} 210 to f₁ 220 and a second frequency band f_{A} 210 to f₃ 230, is of a frequency range that: (a) begins at f_{A} 210, (b) is a part of the second frequency band and (c) is greater than the frequency range of the first frequency band. It is also to be noted that the magnitude of a frequency difference between each pair of successive cutoff frequencies to which the tunable LPF (e.g., 130-a, 130-b) is tunable can be identical or non-identical. For example, for a tunable LPF (e.g., 130-a, 130-b) that is tunable to operate in three frequency bands, as in FIG. 2, the magnitude of the frequency difference between cutoff frequencies f₁ 220 and f₂ 250 can be either: (i) identical to the magnitude of the frequency difference between cutoff frequencies f₂ 250 and f₃ 230 or (ii) non-identical to the magnitude of the frequency difference between cutoff frequencies f₂ 250 and f₃ 230, for example, as provided in the example above, and as illustrated in FIG. 2. It is to be noted that each additional cutoff frequency for the tunable LPF (e.g., 130-a, 130-b), beyond the two cutoff frequencies f₁ 220 and f₃ 230, is between f₁ 220 and f₃ 230 (e.g., f₂ 250).

Attention is now drawn to FIG. 3, one example of a Printed Circuit Board (PCB) design 300 including two tunable LPFs 130, in accordance with the presently disclosed subject matter.

In accordance with the presently disclosed subject matter, a tunable LPF (e.g., 130-a, 130-b) can be configured to pass signal components (e.g., radio transmission signal components) in two or more frequency bands, as detailed earlier herein, inter alia with reference to FIGS. 1 and 2. FIG. 3 is one example of a PCB design 300 including two tunable LPFs 130 on a PCB 310, each of the tunable LPFs 130 being configured to pass signal components (e.g., radio transmission signal components) in two different frequency bands. The upper part of the PCB design 300 includes a first tunable LPF 130-a of the tunable LPFs 130, and the lower part of the PCB design 300 includes a second tunable LPF 130-b of the tunable LPFs 130.

Each of the tunable LPFs 130 (e.g., in the radio system 100) includes a printed part consisting of printed components, and a discrete part consisting of discrete components. Turning to the non-limiting PCB design 300 of FIG. 3, a first tunable LPF 130-a of the tunable LPFs 130 includes printed components (e.g., 320) and discrete components (e.g., 325). Moreover, a second tunable LPF 130-b of the tunable LPFs 130 includes printed components (e.g., 330) and discrete components (e.g., 335).

For each of the tunable LPFs 130, the combination of the printed part (e.g., 320, 330) and the discrete part (e.g., 325, 335) provides the physical infrastructure for enabling the tuning of the respective tunable LPF (e.g., 130-a, 130-b) to any one of the desired cutoff frequencies for the respective tunable LPF (that is, the cutoff frequencies at which the respective tunable LPF is to operate).

The discrete components (e.g., 325, 335) in each of the tunable LPFs 130 include: (a) PIN diodes that are connected to the printed part (e.g., 320, 330) of the respective tunable LPF (e.g., 130-a, 130-b) and (b) additional discrete components (e.g., capacitors, inductors) (not shown in FIG. 3) that are configured for biasing the PIN diodes. In the PCB design 300 of FIG. 3 the first tunable LPF (130-a) includes three PIN diodes 340 (340-a, 340-b and 340-c), and the second tunable LPF (130-b) includes three PIN diodes 350 (350-a, 350-b and 350-c). More generally, a respective tunable LPF (e.g., 130-a, 130-b) that is configured for being operable at two cutoff frequencies (e.g., cutoff frequencies f₁ 220 and f₃ 230) can include three PIN diodes (e.g., 340-a, 340-b, 340-c; 350-a, 350-b, 350-c), for example, as illustrated in FIG. 3. In some cases, the printed components (e.g., 320, 330) of each of the tunable LPFs 130 include one or more physical lines (as illustrated in FIG. 3).

The printed part (e.g., 320, 330) in each of the tunable LPFs 130 includes both: (a) filtering printed components that are physically arranged to form resonant electrical circuits, and (b) at least one biasing printed component that is connected to each of the PIN diodes (e.g., 340-a, 340-b, 340-c; 350-a, 350-b, 350-c) in the respective tunable LPF (e.g., 130-a, 130-b), and configured to bias the respective PIN diode to which it is connected.

The radio system 100 is configured, e.g., by controller 110 (shown in FIG. 1), to tune any one of the tunable LPFs 130 by manipulating the printed part (e.g., 320, 330) and the discrete part (e.g., 325, 335) of the respective tunable LPF (e.g., 130-a, 130-b). The manipulation of both the discrete part (e.g., 325, 335) and the printed part (e.g., 320, 330) of the respective tunable LPF (e.g., 130-a, 130-b) to tune the respective tunable LPF (e.g., 130-a, 130-b) is achieved by controlling a state of the PIN diodes (340, 350) in the respective tunable LPF (e.g., 130-a, 130-b). That is, the radio system 100 is configured, e.g., by controller 110, to change the states of one or more of the PIN diodes (340, 350) in a tunable LPF (e.g., 130-a, 130-b) (and thereby manipulate the discrete part of the tunable LPF) to tune the tunable LPF (e.g., 130-a, 130-b), based on the cutoff frequency that is desired for the tunable LPF (e.g., 130-a, 130-b). The state of any one of the PIN diodes (340, 350) in a respective tunable LPF (e.g., 130-a, 130-b) can be changed quickly, by switching the respective PIN diode, thereby enabling the respective tunable LPF (e.g., 130-a, 130-b) to be tuned at a very fast rate (i.e., the cutoff frequency of the respective tunable LPF can be switched at a very fast rate), e.g., within a few microseconds. In accordance with the present disclosure, changing the states of one or more of the PIN diodes (340, 350) in a respective tunable LPF (e.g., 130-a, 130-b) results in the manipulation (i.e., modification) of electrical values (e.g., the electrical length) of the filtering printed components in the printed part (e.g., 320, 330) of the respective tunable LPF (e.g., 130-a, 130-b). The manipulation of the electrical values of the filtering printed components changes the resonant electrical circuits that are formed by the filtering printed components, resulting in the tuning of the respective tunable LPF (e.g., 130-a, 130-b). In order to enable the tuning of any one of the tunable LPFs 130 to any one of its desired cutoff frequencies, the values of each of the discrete components (e.g., 325, 335) in the respective tunable LPF (e.g., 130-a, 130-b) must be static, since any change to the values of the discrete components would require a corresponding change to the printed part (e.g., 320, 330) of the respective tunable LPF (e.g., 130-a, 130-b) in order to operate the respective tunable LPF (e.g., 130-a, 130-b) at one of its desired cut-off frequencies, which is not possible (no changes can be made to the printed part of the respective tunable LPF, since the printed part is printed into the printed circuit board). This is because the combination of the printed part and the discrete part in any one of the tunable LPFs 130 provides the physical infrastructure for tuning the respective tunable LPF (e.g., 130-a, 130-b).

Each of the tunable LPFs 130 is manufactured with filtering printed components, both discrete and printed biasing components, and PIN diodes (340, 350), as detailed above, in order to enable tuning the respective tunable LPF (e.g., 130-a, 130-b) to operate at any one of the desired cutoff frequencies (e.g., cutoff frequencies f₁ 220 and f₃ 230) for the respective tunable LPF (e.g., 130-a, 130-b), including, inter alia, a highest desired cutoff frequency (e.g., f₃ 230) associated with the widest frequency band at which the respective tunable LPF (e.g., 130-a, 130-b) is capable of operating (i.e., is desired to operate), e.g., frequency band f_{A} 210 to f₃ 230 in FIG. 2. In order to tune any one of the tunable LPFs 130 to operate at its highest cutoff frequency (e.g., f₃ 230) or to maintain any one of the tunable LPFs 130 to operate at its highest cutoff frequency, a controller 110 (e.g., in a radio system 100) turns off (i.e., blocks) each of the PIN diodes (340, 350) in the respective tunable LPF (e.g., 130-a, 130-b). Moreover, in order to tune any one of the tunable LPFs 130 to operate at its lowest cutoff frequency (e.g., f₁ 220) or to maintain any one of the tunable LPFs 130 to operate at its lowest cutoff frequency, a controller 110 (e.g., in a radio system 100) turns on (i.e., activates) each of the PIN diodes (340, 350) in the respective tunable LPF (e.g., 130-a, 130-b). In order to tune any one of the tunable LPFs 130 to operate at a desired cutoff frequency (e.g., f₂ 250) that is between its lowest cutoff frequency (e.g., f₁ 220) and its highest cutoff frequency, e.g., f₃ 230) or to maintain any one of the tunable LPFs 130 to operate at a desired cutoff frequency that is between its lowest cutoff frequency and its highest cutoff frequency, a controller 110 (e.g., in a radio system 100) turns off (i.e., blocks) one or more of the PIN diodes (340, 350) in the respective tunable LPF (e.g., 130-a, 130-b) and turns on (i.e., activates) the remaining PIN diodes (340, 350) in the respective tunable LPF (e.g., 130-a, 130-b), based on the desired cutoff frequency.

In some cases, at least one of the tunable LPFs 130 is capable of operating at a lowest cutoff frequency (e.g., f₁ 220 in FIG. 2) that is less than 65% (e.g., less than 62%, less than 60%, less than 57%, less than 55%, less than 53%, etc.) of a highest cutoff frequency (e.g., f₃ 230 in FIG. 2) at which the respective tunable LPF (e.g., 130-a, 130-b) is capable of operating. In some cases, the PIN diodes (340, 350) of a respective tunable LPF (e.g., 130-a, 130-b) have the following parasitic characteristics: (a) a series resistance at 10 milliamperes (mA) that is less than one Ohm (Ω) to form a short circuit, and (b) a capacitance at 50-400 Volts (V) that is between 0.33 and 0.37 picofarads (pF) (e.g., 0.33 pF, 0.335 pF, 0.34 pF, 0.345 pF, 0.35 pF, 0.355 pF, 0.36 pF, 0.365 pF, 0.37 pF) to form an open circuit. The manufacturing of the respective tunable LPF (e.g., 130-a, 130-b) with such PIN diodes (340, 350) enables the respective tunable LPF (e.g., 130-a, 130-b) to operate at a lowest cutoff frequency that is less than 65% of its highest cutoff frequency. Put differently, in some cases, the PIN diodes (340, 350) have parasitic characteristics for enabling the respective tunable LPF (e.g., 130-a, 130-b) to operate at a lowest cutoff frequency that is less than 65% of the highest cutoff frequency at which the respective tunable LPF (e.g., 130-a, 130-b) is capable of operating. An example PIN diode that can be used for the PIN diodes (340, 350) of any one of the tunable LPFs (e.g., 130-a, 130-b) is the APD2220-219, manufactured by Skyworks Solutions Inc.

In some cases, the tunable LPFs 130 are to operate at a high power, for example, with a voltage of between approximately 50V and approximately 400V. In such cases, the PIN diodes (340, 350) are selected to have a blocking voltage that is consistent with the high power at which the tunable LPFs 130 are to operate.

In some cases, three PIN diodes (340-a, 340-b, 340-c; 350-a, 350-b, 350-c) are included in a tunable LPF (e.g., 130-a, 130-b) that is tunable to two cutoff frequencies, as illustrated in FIG. 3. In some cases, the lower cutoff frequency (e.g., f₁ in FIG. 2) of such a tunable LPF is less than 65% of the higher cutoff frequency (e.g., f₃ in FIG. 2) of the tunable LPF. For each additional cutoff frequency (e.g., f₂ in FIG. 2) beyond two cutoff frequencies at which it is desired that the tunable LPF will be capable of operating, an additional PIN diode, e.g., in addition to the three PIN diodes (340-a, 340-b, 340-c; 350-a, 350-b, 350-c), can be included in the tunable LPF (e.g., 130-a, 130-b), e.g., in parallel to one of the PIN diodes that are required to enable the tunable LPF to operate at two cutoff frequencies. In some cases, the lowest cutoff frequency of such a tunable LPF (e.g., 130-a, 130-b) is less than 65% of its highest cutoff frequency.

It is to be noted that a tunable LPF 130, as described in the present disclosure, can be used in environments other than a radio system 100.

Attention is now drawn to FIG. 4, a flowchart illustrating one example of a sequence of operations 400 for processing a given radio transmission signal, in accordance with the presently disclosed subject matter.

In accordance with the presently disclosed subject matter, a radio system 100 includes one or more tunable LPFs 130 coupled between a wide-band transmitter 120 of the radio system 100 and a transmission antenna 155, as detailed earlier herein, inter alia with reference to FIG. 1. Each of the tunable LPFs 130 includes a printed part consisting of printed components (e.g., 320, 330) and a discrete part consisting of discrete components (e.g., 325, 335), as detailed earlier herein, inter alia with reference to FIG. 3.

In some cases, radio system 100 can be configured, e.g., using controller 110, to tune a respective tunable low pass filter (LPF) (e.g., 130-a, 130-b) of the tunable LPFs 130 for filtering the given radio transmission signal. The respective tunable LPF (e.g., 130-a, 130-b) is tuned by manipulating the printed part of the respective tunable LPF and the discrete part of the respective tunable LPF, as detailed earlier herein, inter alia with reference to FIG. 3 (block 404).

Wide-band transmitter 120 can be configured to generate the given radio transmission signal (block 408).

The respective tunable LPF (e.g., 130-a, 130-b) that is tuned to filter the given radio transmission signal can be configured to filter the given radio transmission signal (block 412), prior to a transmission of the given radio transmission signal via the transmission antenna 155.

It is to be noted that, with reference to FIG. 4, some of the blocks can be integrated into a consolidated block or can be broken down to a few blocks and/or other blocks may be added. It is to be further noted that some of the blocks are optional. It should be also noted that whilst the flow diagrams are described also with reference to the system elements that realizes them, this is by no means binding, and the blocks can be performed by elements other than those described herein.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

It will also be understood that the system according to the presently disclosed subject matter can be implemented, at least partly, as a suitably programmed computer. Likewise, the presently disclosed subject matter contemplates a computer program being readable by a computer for executing the disclosed method. The presently disclosed subject matter further contemplates a machine-readable memory tangibly embodying a program of instructions executable by the machine for executing the disclosed method.

1. A radio system, comprising:
a wide-band transmitter;
one or more tunable low pass filters (LPFs), coupled between the wide-band transmitter and a transmission antenna, each tunable LPF of the tunable LPFs being configured to be operable at two or more cutoff frequencies, and including:
a printed part consisting of printed components; and
a discrete part consisting of discrete components, the discrete components including PIN diodes that are connected to the printed part; and
a controller configured to tune a given tunable LPF of the tunable LPFs to any one of the two or more cutoff frequencies at which the given tunable LPF is operable by changing a state of one or more respective PIN diodes of the PIN diodes in the given tunable LPF;
wherein the controller is configured to: (a) tune the given tunable LPF to a highest cutoff frequency of the two or more cut-off frequencies at which it is operable by causing each of the PIN diodes in the given tunable LPF to be turned off and (b) tune the given tunable LPF to a lowest cutoff frequency of the two or more cut-off frequencies at which it is operable by causing each of the PIN diodes in the given tunable LPF to be turned on.

2. The radio system of claim 1, wherein the lowest cutoff frequency at which the given tunable LPF is capable of operating is less than 65% of the highest cutoff frequency at which the given tunable LPF is capable of operating.

3. The radio system of claim 1, wherein the printed components in the printed part of the given tunable LPF include filtering printed components that are physically arranged to form a resonant electrical circuit, and wherein changing the state of the one or more respective PIN diodes results in the manipulation of electrical values of the filtering printed components, thereby resulting in the tuning of the given tunable LPF.

4. The radio system of claim 3, wherein the electrical values include an electrical length of the filtering printed components.

5. The radio system of claim 1, wherein the given tunable LPF is configured to be operable at three or more cutoff frequencies; and
wherein the controller is configured to tune the given tunable LPF to a desired cutoff frequency that is between the lowest cutoff frequency and the highest cutoff frequency by causing, based on the desired cutoff frequency, one or more of the PIN diodes in the given tunable LPF to be turned off and the remaining PIN diodes in the given tunable LPF to be turned on.

6. The radio system of claim 2, wherein parasitic characteristics of the PIN diodes enable the given tunable LPF to operate at the lowest cutoff frequency.

7. The radio system of claim 1, wherein parasitic characteristics of the PIN diodes include: (a) a series resistance at 10 milliamperes (mA) that is less than one Ohm (Ω) to form a short circuit, and (b) a capacitance at 50-400 Volts (V) that is between 0.33 and 0.37 picofarads (pF) to form an open circuit.

8. A tunable low-pass filter (LPF), comprising:
a printed part consisting of printed components; and
a discrete part consisting of discrete components, the discrete components including PIN diodes that are connected to the printed part;
wherein the tunable LPF is configured to be operable at two or more cutoff frequencies;
wherein the tunable LPF is tunable to any one of the two or more cutoff frequencies by changing a state of one or more respective PIN diodes of the PIN diodes; and
wherein the tunable LPF is tunable to: (a) a highest cutoff frequency of the two or more cutoff frequencies, by causing each of the PIN diodes in the tunable LPF to be turned off and (b) a lowest cutoff frequency of the two or more cutoff frequencies, by causing each of the PIN diodes in the tunable LPF to be turned on.

9. The tunable LPF of claim 8, wherein the lowest cutoff frequency at which the tunable LPF is capable of operating is less than 65% of the highest cutoff frequency at which the tunable LPF is capable of operating.

10. The tunable LPF of claim 8, wherein the printed components in the printed part of the tunable LPF include filtering printed components that are physically arranged to form a resonant electrical circuit, and wherein changing the state of the one or more respective PIN diodes results in the manipulation of electrical values of the filtering printed components, thereby resulting in the tuning of the tunable LPF.

11. The tunable LPF of claim 10, wherein the electrical values include an electrical length of the filtering printed components.

12. The tunable LPF of claim 8, wherein the tunable LPF is configured to be operable at three or more cutoff frequencies; and
wherein the tunable LPF is tunable to a desired cutoff frequency that is between the lowest cutoff frequency and the highest cutoff frequency by causing, based on the desired cutoff frequency, one or more of the PIN diodes in the tunable LPF to be turned off and the remaining PIN diodes in the tunable LPF to be turned on.

13. The tunable LPF of claim 8, wherein parasitic characteristics of the PIN diodes enable the tunable LPF to operate at the lowest cutoff frequency.

14. The tunable LPF of claim 8, wherein parasitic characteristics of the PIN diodes include: (a) a series resistance at 10 milliamperes (mA) that is less than one Ohm (Ω) to form a short circuit, and (b) a capacitance at 50-400 Volts (V) that is between 0.33 and 0.37 picofarads (pF) to form an open circuit.

15. A method for processing a radio transmission signal, the method comprising:
tuning a tunable low pass filter (LPF), by a controller, for filtering the radio transmission signal;
generating, by a wide-band transmitter, the radio transmission signal; and
filtering, by the tunable LPF, the radio transmission signal;
wherein the tunable LPF includes:
a printed part consisting of printed components; and
a discrete part consisting of discrete components, the discrete components including PIN diodes that are connected to the printed part;
wherein the tunable LPF is configured to be operable at two or more cutoff frequencies;
wherein the tunable LPF is tunable to any one of the two or more cutoff frequencies by the controller changing a state of one or more respective PIN diodes of the PIN diodes; and
wherein the tunable LPF is tuned to either: (a) a highest cutoff frequency of the two or more cutoff frequencies, by the controller causing each of the PIN diodes in the tunable LPF to be turned off, or (b) a lowest cutoff frequency of the two or more cutoff frequencies, by the controller causing each of the PIN diodes in the tunable LPF to be turned on.

16. The method of claim 15, wherein the lowest cutoff frequency at which the tunable LPF is capable of operating is less than 65% of the highest cutoff frequency at which the tunable LPF is capable of operating.

17. The method of claim 15, wherein the printed components in the printed part include filtering printed components that are physically arranged to form a resonant electrical circuit, and wherein changing the state of the one or more respective PIN diodes results in the manipulation of electrical values of the filtering printed components, thereby resulting in the tuning of the tunable LPF.

18. The method of claim 17, wherein the electrical values include an electrical length of the filtering printed components.

19. The method of claim 16, wherein parasitic characteristics of the PIN diodes enable the tunable LPF to operate at the lowest cutoff frequency.

20. The method of claim 15, wherein parasitic characteristics of the PIN diodes include: (a) a series resistance at 10 milliamperes (mA) that is less than one Ohm (Ω) to form a short circuit, and (b) a capacitance at 50-400 Volts (V) that is between 0.33 and 0.37 picofarads (pF) to form an open circuit.
